(19) United States
(12) Patent Application Publication
(10) Pub. No.: US 2025/0202435 A1
(43) Pub. Date: Jun. 19, 2025

(54) AMPLIFIER CIRCUIT

(71) Applicant: Sumitomo Electric Industries, Ltd., Osaka (JP)

(72) Inventor: Hirotaka ASAMI, Osaka-shi (JP)

(73) Assignee: Sumitomo Electric Industries, Ltd., Osaka (JP)

(21) Appl. No.: 18/975,520

(22) Filed: Dec. 10, 2024

(30) Foreign Application Priority Data
Dec. 14, 2023 (JP) 2023-211455

(51) Int. Cl. H03F 1/02; H03F 1/56; H03F 3/60

(52) U.S. Cl. CPC H03F 1/0288; H03F 1/565; H03F 3/607

(57) ABSTRACT

An amplifier circuit includes a first divider dividing an input signal into first and second signals, a control amplifier outputting a third signal, a second divider dividing the second signal into fourth and fifth signals, a first auxiliary amplifier outputting a sixth signal, a second auxiliary amplifier outputting a seventh signal, and a branch line coupler including first to fourth ends and first to fourth transmission lines. A first characteristic impedance at the center frequency of the first transmission line and the third transmission line is higher than a reference impedance, and a second characteristic impedance at the center frequency of the second transmission line and the fourth transmission line is lower than the first characteristic impedances/√2. An amplitude of a power of the seventh signal is larger than an amplitude of a power of the sixth signal.

### CROSS REFERENCE TO RELATED APPLICATIONS

This application claims priority based on Japanese Patent Application No. 2023-211455 filed on Dec. 14, 2023, and the entire contents of the Japanese patent applications are incorporated herein by reference.

### FIELD

A certain aspect of the embodiments is related to an amplifier circuit.

### BACKGROUND

An LMBA (Load Modulated Balanced Amplifier) includes a control amplifier for amplifying one of the signals into which an input signal is divided, and a balance amplifier for amplifying the other signal to which the input signal is divided. It is known to use a 3 dB branch line coupler as a combiner for combining an output signal of the control amplifier and an output signal of the balance amplifier (for example, Patent Document 1: U.S. Patent Application Publication No. 2022/0255506).

### SUMMARY

An amplifier circuit according to the present disclosure includes a first divider that divides an input signal into a first signal and a second signal; a control amplifier that amplifies the first signal and outputs an amplified signal as a third signal; a second divider that divides the second signal into a fourth signal and a fifth signal having different phases at a center frequency of an operating band; a first auxiliary amplifier that amplifies the fourth signal and outputs an amplified signal as a sixth signal; a second auxiliary amplifier that amplifies the fifth signal and outputs an amplified signal as a seventh signal; and a branch line coupler including: a first end to which the sixth signal is input; a second end to which the seventh signal is input; a third end to which the third signal is input; a fourth end from which an output signal is output; a first transmission line connecting the first end to the second end; a second transmission line connecting the first end to the third end; a third transmission line connecting the third end to the fourth end; and a fourth transmission line connecting the second end to the fourth end, wherein a first characteristic impedance at the center frequency of the first transmission line and the third transmission line is higher than a reference impedance, and a second characteristic impedance at the center frequency of the second transmission line and the fourth transmission line is lower than the first characteristic impedance/√2, wherein an amplitude of a power of the seventh signal is larger than an amplitude of a power of the sixth signal.

### BRIEF DESCRIPTION OF DRAWINGS

FIG. 1 is a circuit diagram of an amplifier circuit according to a first embodiment.

FIG. 2 is a circuit diagram illustrating a divider in the first embodiment.

FIG. 3 is a circuit diagram illustrating a combiner in the first embodiment.

FIG. 4 is a plan view of a branch line coupler in the first embodiment.

FIG. 5 is a circuit diagram of an amplifier circuit according to a first comparative example.

FIG. 6 is a circuit diagram illustrating a part of an amplifier circuit in a second comparative example.

FIG. 7 is a circuit diagram illustrating a part of an amplifier circuit in the second comparative example.

FIG. 8 is a schematic diagram illustrating the operation of the combiner in a third comparative example and the first embodiment.

FIG. 9 is a circuit diagram illustrating a balance amplifier in the third comparative example.

FIG. 10 is a circuit diagram illustrating a balance amplifier in an example 1 of the first embodiment.

FIG. 11 is a circuit diagram illustrating a balance amplifier in an example 2 of the first embodiment.

### DETAILED DESCRIPTION OF EMBODIMENTS

In the LMBA, a distributed constant type branch line coupler using a ¼ wavelength line is used as a 3 dB branch line coupler from the viewpoint of the characteristics of the coupler. However, since the ¼ wavelength line is used, the distributed constant type branch line coupler is large, and the size of the amplifier circuit is increased.

The present disclosure has been made in view of the above problems, and an object of the present disclosure is to provide an amplifier circuit capable of being downsized.

### DETAILS OF EMBODIMENTS OF THE PRESENT DISCLOSURE

First, the contents of the embodiments of this disclosure are listed and explained.

(1) An amplifier circuit according to the present disclosure includes a first divider that divides an input signal into a first signal and a second signal; a control amplifier that amplifies the first signal and outputs an amplified signal as a third signal; a second divider that divides the second signal into a fourth signal and a fifth signal having different phases at a center frequency of an operating band; a first auxiliary amplifier that amplifies the fourth signal and outputs an amplified signal as a sixth signal; a second auxiliary amplifier that amplifies the fifth signal and outputs an amplified signal as a seventh signal; and a branch line coupler including: a first end to which the sixth signal is input; a second end to which the seventh signal is input; a third end to which the third signal is input; a fourth end from which an output signal is output; a first transmission line connecting the first end to the second end; a second transmission line connecting the first end to the third end; a third transmission line connecting the third end to the fourth end; and a fourth transmission line connecting the second end to the fourth end, wherein a first characteristic impedance at the center frequency of the first transmission line and the third transmission line is higher than a reference impedance, and a second characteristic impedance at the center frequency of the second transmission line and the fourth transmission line is lower than the first characteristic impedance/√2, wherein an amplitude of a power of the seventh signal is larger than an amplitude of a power of the sixth signal. This makes it possible to downsize the branch line coupler and suppress the variation in a load impedance of the control amplifier.

(2) In the above (1), a difference between a first ratio of the amplitude of the power of the seventh signal to an amplitude of the power of the sixth signal and a second ratio of an amplitude of a power of an eighth signal divided from the sixth signal having the center frequency input to the first end to an amplitude of a power of a ninth signal divided from the sixth signal may be 1 dB or less. The eighth signal and the ninth signal may be transmitted to the third terminal and the fourth end, respectively. This makes it possible to suppress the variation in the load impedance of the control amplifier.

(3) In the above (2), the second ratio may be 2 dB or more. This allows the branch line coupler to be downsized.

(4) In any of the above (1) to (3), the first characteristic impedance may be 1.2 times or more the reference impedance, and the second characteristic impedance may be 0.9/√2 times or less the first characteristic impedance. This allows the branch line coupler to be downsized.

(5) In any of the above (1) to (4), first widths of the first transmission line and the third transmission line may be smaller than second widths of fifth transmission lines connected to the first end, the second end, the third end, and the fourth end, and third widths of the second transmission line and the fourth transmission line may be larger than the first widths. This allows the branch line coupler to be downsized.

(6) In any of the above (1) to (5), a saturation power of the second auxiliary amplifier may be larger than a saturation power of the first auxiliary amplifier. This makes it possible to suppress the variation in the load impedance of the control amplifier.

(7) In any of the above (1) to (5), a ratio of a saturation power of the second auxiliary amplifier to a saturation power of the first auxiliary amplifier may be 2 dB or more. This makes it possible to suppress the variation in the load impedance of the control amplifier.

(8) In any one of the above (1) to (5), a physical size of the second auxiliary amplifier may be larger than a physical size of the first auxiliary amplifier. This makes it possible to suppress the variation in the load impedance of the control amplifier.

(9) In any one of the above (1) to (8), an amplitude of a power of the fifth signal may be larger than an amplitude of a power of the fourth signal. This makes it possible to suppress the variation in the load impedance of the control amplifier.

(10) In the above (9), a ratio of the amplitude of the power of the fifth signal to the amplitude of the power of the fourth signal may be 2 dB or more. This makes it possible to suppress the variation in the load impedance of the control amplifier.

Specific examples of an amplifier circuit according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

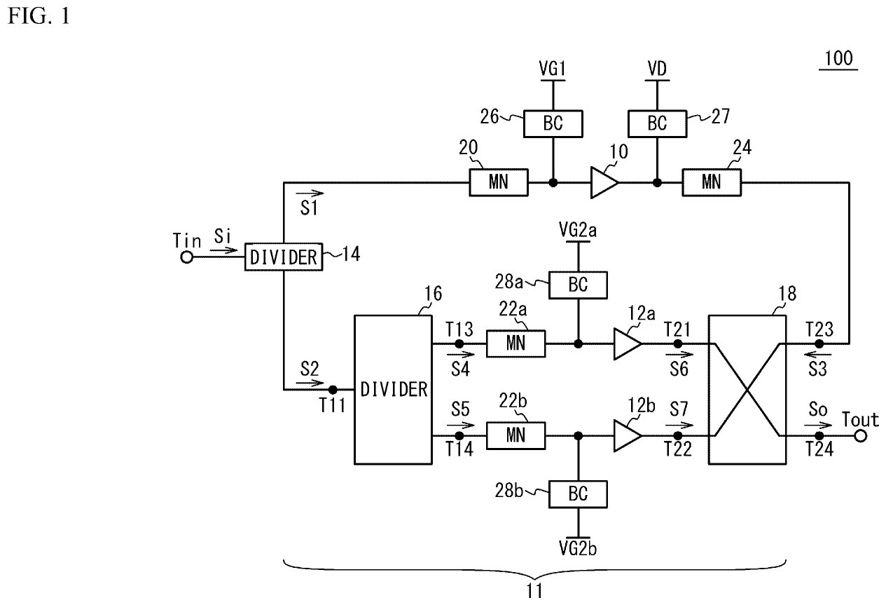

FIG. 1 is a circuit diagram of an amplifier circuit according to a first embodiment. As illustrated in FIG. 1, in an amplifier circuit 100 of the first embodiment, a control amplifier 10 and a balance amplifier 11 are connected in parallel between an input terminal Tin and an output terminal Tout. A high-frequency signal is input to the input terminal Tin as an input signal Si. When the amplifier circuit 100 is used in a base station for mobile communication, the frequency of the high-frequency signal is, for example, 0.5 GHz to 10 GHz. A divider 14 (first divider) divides the input signal Si input to the input terminal Tin into signals S1 (first signal) and S2 (second signal).

The signal S1 passes through a matching circuit 20 and is input to the control amplifier 10. Each of matching circuits are denoted as “MN (Matching network)” in FIG. 1. The matching circuit 20 matches an impedance viewed from the divider 14 toward the matching circuit 20 with an impedance viewed from the matching circuit 20 toward the control amplifier 10. A bias circuit (BC) 26 for supplying an input bias voltage VG1 to the control amplifier 10 is connected to a node in a line between the divider 14 and the control amplifier 10. The bias circuit 26 supplies the input bias voltage VG1 to the control amplifier 10, and suppresses leakage of the signal S1 to a power supply supplying the input bias voltage VG1.

The control amplifier 10 amplifies the signal S1 and outputs the amplified signal as a signal S3 (third signal). The signal S3 amplified by the control amplifier 10 passes through a matching circuit 24 and is input to an end T23 of a combiner 18. The matching circuit 24 matches an impedance viewed from the control amplifier 10 toward the matching circuit 24 with an impedance viewed from the matching circuit 24 toward the combiner 18. A bias circuit 27 for supplying an output bias voltage VD to the control amplifier 10 is connected to a node in a line between the control amplifier 10 and the combiner 18. The bias circuit 27 supplies the output bias voltage VD to the control amplifier 10, and suppresses leakage of the signal S3 to the power supply supplying the output bias voltage VD.

A signal S2 divided by the divider 14 is input to the balance amplifier 11. The balance amplifier 11 includes a divider 16, auxiliary amplifiers 12a and 12b, and the combiner 18. The divider 16 (second divider) divides the signal S2 input to an end T11 into signals S4 (fourth signal) and S5 (fifth signal), and outputs them from ends T13 and T14, respectively. The signal S5 is delayed in phase by, for example, about 90° from the phase of the signal S4. The amplitudes of the signals S5 and S4 are substantially the same as each other, for example. The angle 90° may not be strictly 90°, and may be, for example, 85° or more and 95° or less, or 88° or more and 92° or less. The same applies to the combiner 18.

The signal S4 passes through a matching circuit 22a and is input to the auxiliary amplifier 12a. The matching circuit 22a matches an impedance viewed from the divider 16 toward the matching circuit 22a with an impedance viewed from the matching circuit 22a toward the auxiliary amplifier 12a. A bias circuit 28a for supplying an input bias voltage VG2a to the auxiliary amplifier 12a is connected to a node in a line between the divider 16 and the auxiliary amplifier 12a. The bias circuit 28a supplies the input bias voltage VG2a to the auxiliary amplifier 12a, and suppresses leakage of the signal S4 to the power supply supplying the input bias voltage VG2a. The auxiliary amplifier 12a (first auxiliary amplifier) amplifies the signal S4 and outputs the amplified signal as a signal S6 (sixth signal). The signal S6 amplified by the auxiliary amplifier 12a is input to an end T21 of the combiner 18.

The signal S5 passes through a matching circuit 22b and is input to the auxiliary amplifier 12b. The matching circuit 22b matches an impedance viewed from the divider 16 toward the matching circuit 22b with an impedance viewed from the matching circuit 22b toward the auxiliary amplifier 12b. A bias circuit 28b for supplying an input bias voltage VG2b to the auxiliary amplifier 12b is connected to a node in a line between the divider 16 and the auxiliary amplifier 12b. The bias circuit 28b supplies the input bias voltage VG2b to the auxiliary amplifier 12b, and suppresses the leakage of the signal S5 to the power supply supplying the input bias voltage VG2b. The auxiliary amplifier 12b (second auxiliary amplifier) amplifies the signal S5 and outputs the amplified signal as a signal S7 (seventh signal). The signal S7 amplified by the auxiliary amplifier 12b is input to an end T22 of the combiner 18.

Matching circuits for matching impedances may be connected between the auxiliary amplifiers 12a and 12b and the combiner 18. In the first embodiment, a signal of the control amplifier 10 adjusts the loads of the auxiliary amplifiers 12a and 12b. For this reason, the matching circuits need not be provided between the auxiliary amplifiers 12a and 12b and the combiner 18. A harmonic processing circuit may be connected between the auxiliary amplifiers 12a and 12b and the combiner 18 to reflect harmonic signals in the signals S6 and S7. The harmonic signals are, for example, second harmonics or third harmonics when the operating frequency of the amplifier circuit is a fundamental harmonic. Bias circuits for supplying output bias voltages to the auxiliary amplifiers 12a and 12b may be provided between the auxiliary amplifiers 12a and 12b and the combiner 18. In the first embodiment, the output bias voltages of the auxiliary amplifiers 12a and 12b are supplied from the bias circuit 27 to the auxiliary amplifiers 12a and 12b through the combiner 18.

The combiner 18 is, for example, a distributed constant type branch line coupler. The ends T21 to T24 are terminals of the branch line coupler, and the ends T21 and T24 are located diagonally, and the ends T22 and T23 are located diagonally. The signal S6 is input to the end T21 (first end). The signal S7 is input to the end T22 (second end). The signal S3 is input to the end T23 (third end). An output signal So is output from the end T24 (fourth end). The combiner 18 combines the signals S3, S6 and S7 and outputs the combined signal as an output signal So.

The control amplifier 10 and the auxiliary amplifiers 12a and 12b are transistors such as FET (Field Effect Transistor), and the sources thereof are grounded, and high-frequency signals are input to the gates thereof and high-frequency signals are output from the drains thereof. The FET is, for example, a GaN HEMT (Gallium Nitride High Electron Mobility Transistor) or an LDMOS (Laterally Diffused Metal Oxide Semiconductor). Each of the control amplifier 10 and the auxiliary amplifiers 12a and 12b may be provided with multistage FETs. When the control amplifier 10 and the auxiliary amplifiers 12a and 12b are FETs, the input bias voltages VG1, VG2a and VG2b are gate bias voltages, and the output bias voltage VD is a drain bias voltage.

[Divider 16]

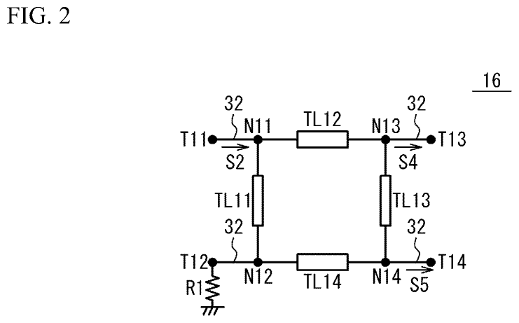

FIG. 2 is a circuit diagram illustrating the divider 16 in the first embodiment. As illustrated in FIG. 2, the divider 16 uses the distributed constant type branch line coupler. Transmission lines TL11, TL12, TL13, and TL14 are connected between nodes N11 and N12, between nodes N11 and N13, between nodes N13 and N14, and between nodes N12 and N14, respectively. The transmission lines TL11 to TL14 are λ/4 transmission lines. The electrical length of the λ/4 transmission line is, for example, approximately λ/4. Here, λ is the wavelength of a center frequency fo of the operating band of the amplifier circuit 100. The electrical length of the λ/4 transmission line is not strictly limited to λ/4, and may be, for example, 3λ/16 or more and 5λ/16 or less, or 7λ/32 or more and 9λ/32 or less. The same applies to other λ/4 transmission lines. Transmission lines 32 are connected between the end T11 and the node N11, between the end T12 and the node N12, between the end T13 and the node N13, and between the end T14 and the node N14. The signal S2 input to the end T11 is divided into the signals S4 and S5, and the signals S4 and S5 are output from the ends T13 and T14, respectively. The phase of the center frequency fo of the signal S5 is delayed by approximately 90° from the phase of the center frequency fo of the signal S4. The end T12 is connected to a reference potential via a resistor R1. The resistance value of the resistor R1 is, for example, a reference impedance (for example, 50Ω).

The divider 16 may be a divider using a Wilkinson type divider and a λ/4 transmission line, a lumped constant type branch line coupler using inductors and capacitors, a distributed coupling type coupler in which two transmission lines are electromagnetically coupled, or a dense-wound coil coupler in which two inductors are electromagnetically coupled.

### [Combiner 18]

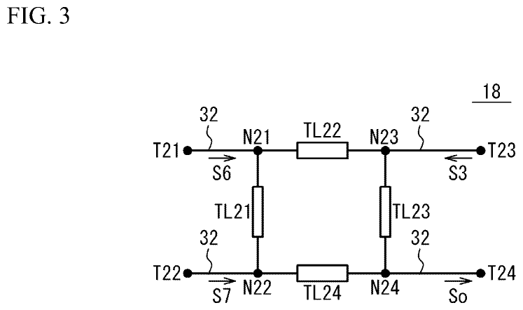

FIG. 3 is a circuit diagram illustrating an example of the combiner 18 in the first embodiment. As illustrated in FIG. 3, the combiner 18 is a distributed constant type branch line coupler. Transmission lines TL21 (first transmission line), TL22 (second transmission line), TL23 (third transmission line), and TL24 (fourth transmission line) are connected between nodes N21 and N22, between nodes N21 and N23, between nodes N23 and N24, and between nodes N22 and N24, respectively. The transmission lines TL21 to TL24 are λ/4 transmission lines. The transmission lines 32 are connected between the end T21 and the node N21, between the end T22 and the node N22, between the end T23 and the node N23, and between the end T24 and the node N24, respectively. The signal S6 input to the end T21, the signal S7 input to the end T22, and the signal S3 input to the end T23 are combined, and a combined signal is output from the end T24 as the output signal So.

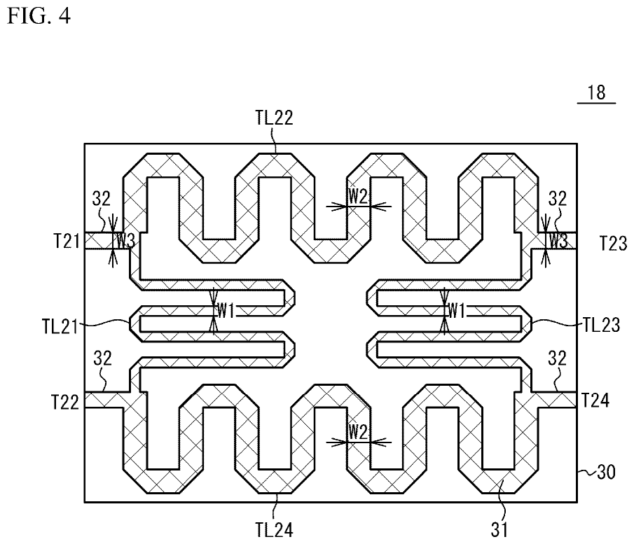

FIG. 4 is a plan view of the branch line coupler in the first embodiment. As illustrated in FIG. 4, the transmission lines TL21 to TL24 and the transmission lines 32 are formed by a conductor pattern 31 provided on a dielectric substrate 30. A metal layer to which the reference potential is supplied is provided on the lower surface of the dielectric substrate 30. The transmission lines TL21 to TL24 and the transmission lines 32 are microstrip lines. The characteristic impedance of the transmission line 32 is a reference impedance Zo and is, for example, 50Ω. Each of the transmission lines TL21 and TL23 has a width W1, each of the transmission lines TL22 and TL24 has a width W2, and the transmission line 32 has a width W3.

When the dielectric substrate 30 is a mounting substrate, the dielectric substrate 30 is, for example, a glass epoxy resin substrate or a ceramic substrate. In the case where the divider 16 and the combiner 18 are monolithically integrated with the control amplifier 10 and the auxiliary amplifiers 12a and 12b, the dielectric substrate 30 is, for example, a silicon carbide substrate, a gallium nitride substrate, a gallium arsenide substrate or a silicon substrate. The conductor pattern 31 is a metal layer such as a gold layer, a copper layer, or an aluminum layer.

The matching circuits 20, 22a, 22b, and 24 are passive circuits including inductors and capacitors, and are, for example, inductors connected in series, π-type circuits of CLC configuration, T-type circuits of LCL configuration, L-type circuits of LC configuration, or circuits combining these circuits.

The control amplifier 10 corresponds to a main amplifier of the Doherty amplifier circuit, and the auxiliary amplifiers 12a and 12b correspond to peak amplifiers of the Doherty amplifier circuit. The control amplifier 10 operates in class AB or class B, and the auxiliary amplifiers 12a and 12b operate in class C. When the input power of the input signal Si is small, the control amplifier 10 mainly amplifies the input signal Si. When the input power is increased, the auxiliary amplifiers 12a and 12b amplify the peak of the input signal Si in addition to the control amplifier 10. As a result, the control amplifier 10 and the auxiliary amplifiers 12a and 12b amplify the input signal Si.

### First Comparative Example

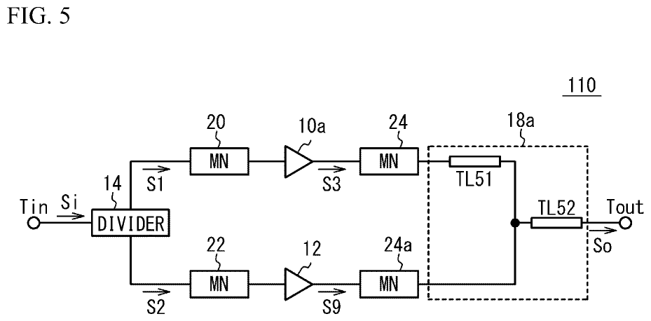

As a first comparative example, a Doherty amplifier circuit will be described. FIG. 5 is a circuit diagram of an amplifier circuit according to the first comparative example. As illustrated in FIG. 5, in an amplifier circuit 110 of the first comparative example, a main amplifier 10a and a peak amplifier 12 are provided in parallel between the input terminal Tin and the output terminal Tout. The divider 14 divides the input signal Si into the signals S1 and S2. The main amplifier 10a amplifies the signal S1 that has passed through the matching circuit 20, and outputs the amplified signal as the signal S3 to a combiner 18a via the matching circuit 24. The peak amplifier 12 amplifies the signal S2 that has passed through a matching circuit 22, and outputs the amplified signal as a signal S9 to the combiner 18a via a matching circuit 24a.

The combiner 18a includes λ/4 transmission lines TL51 and TL52 as impedance converters. An impedance viewed from the matching circuit 24 toward the combiner 18a and a load impedance of the peak amplifier 12 are modulated using the λ/4 transmission lines TL51 and TL52.

In the first comparative example, when the frequency is changed, the electric length of the λ/4 transmission line is shifted from λ/4, and therefore it is difficult to widen the operating band. In one example, the specific bandwidth of the combiner using the λ/4 transmission lines TL51 and TL52 is about 8%. In the LMBA of the first embodiment, since the branch line coupler is used to modulate the load impedance of the auxiliary amplifiers 12a and 12b, the operating band can be widened. The specific bandwidth of the branch line coupler is, for example, 120% at the maximum in a commercially available hybrid coupler. In this way, the LMBA allows the combiner 18 to have a wider bandwidth.

### Second Comparative Example

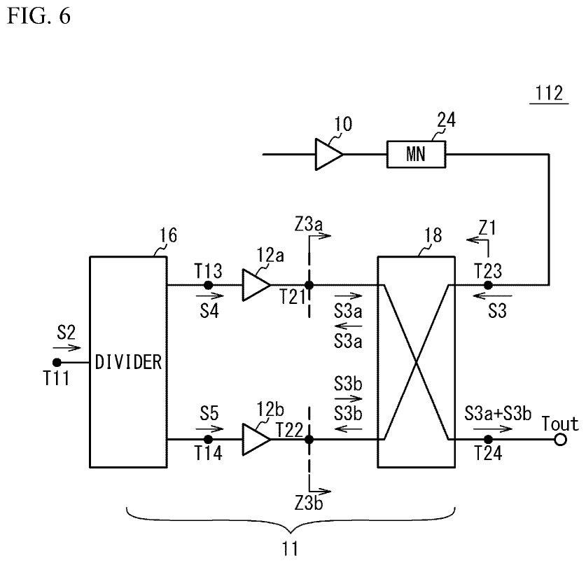

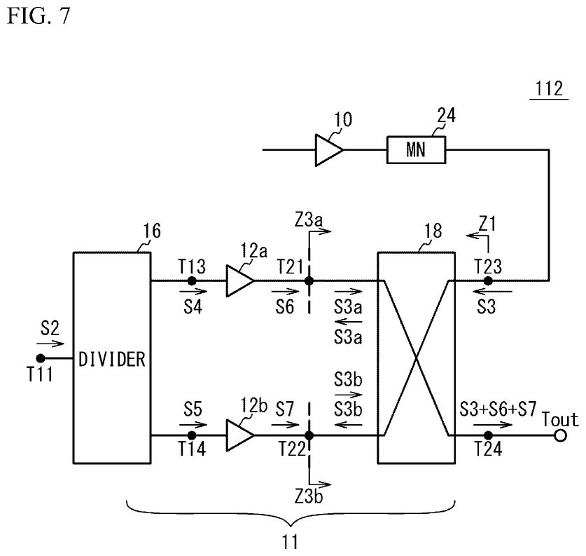

As a second comparative example, an LMBA in which the combination ratio of the combiner 18 is 1:1 will be described. FIGS. 6 and 7 are circuit diagrams illustrating a part of an amplifier circuit 112 in the comparative example 2. FIGS. 6 and 7 illustrate the circuits of the control amplifier 10 and the balance amplifier 11 and subsequent circuits. In the second comparative example, the combination ratio of the powers at which the combiner 18 combines the signals S6 and S7 in FIG. 7 is 1:1.

Referring to FIG. 6, when the power of the input signal Si is small and the auxiliary amplifiers 12a and 12b do not operate, the signal S3 input from the end T23 to the combiner 18 is divided into two signals S3a and S3b at the ends T21 and T22. The ratio of the amplitudes of the powers of the signals S3a and S3b is 1:1. The phase of the signal S3b at the end T22 is delayed by 90° from the phase of the signal S3a at the end T21. The signals S3a and S3b are reflected at ends T21 and T22, respectively. The reflected signals S3a and S3b are combined at the end T24. The phase of the signal S3a reflected at the end T21 is delayed by 90° from the phase of the signal S3b reflected at the end T22. As a result, the phases of the signals S3a and S3b are aligned at the end T24 to combine the signal S3. The combined signal S3 is output to the output terminal Tout as the output signal So.

At this time, the reflection coefficient (i.e., the absolute values of the impedances Z3a and Z3b) viewed from the auxiliary amplifiers 12a and 12b toward the combiner 18 is greater than 1, and impedances Z3a and Z3b serving as the loads of the auxiliary amplifiers 12a and 12b are substantially high. On the other hand, an impedance Z1 viewed from the matching circuit 24 toward the end T23 is the reference impedance (e.g., 50Ω) which is an input impedance of the end T23.

Next, referring to FIG. 7, when the power of the input signal Si is large and the auxiliary amplifiers 12a and 12b operate, the phase of the signal S7 is delayed by 90° from that of the signal S6. The phase of the signal S3b at the end T22 is delayed by 90° from that of the signal S3a at the end T21. Accordingly, by appropriately adjusting a phase difference between the signals S1 and S2, the phases of the signals S6 and S3a at the end T21 are optimized (for example, the phases of the signals S6 and S3a are aligned), and the phases of the signals S7 and S3b at the end T22 are optimized (for example, the phases of the signals S7 and S3b are aligned). A signal S6+S3a combined at the end T21 and a signal S7+S3b combined at the end T22 are combined at the end T24. A combined signal S3+S6+S7 is output to the output terminal Tout as the output signal So.

At this time, the signals incident from the auxiliary amplifiers 12a and 12b to the ends T21 and T22 are substantially the signals S6+S3a and S7+S3b, respectively, and the signals reflected at the ends T21 and T22 are substantially the signals S3a and S3b, respectively. Therefore, the reflection coefficients (i.e., the absolute values of the impedances Z3a and Z3b) of the auxiliary amplifiers 12a and 12b at the ends T21 and T22 are smaller than 1, and the larger the amplitudes of the powers of the signals S6 and S7 are, the smaller the reflection coefficients become. The impedances Z3a and Z3b, which are the loads of the auxiliary amplifiers 12a and 12b, become substantially lower as the amplitudes of the powers of the signals S6 and S7 increase. In this way, the combiner 18 modulates the impedances Z3a and Z3b, which are the loads viewed from the auxiliary amplifiers 12a and 12b toward the combiner 18, depending on the amplitudes of the signals S6 and S7. On the other hand, the impedance Z1 from the matching circuit 24 toward the end T23 is the reference impedance (for example, 50Ω) regardless of the magnitude of the amplitudes of the signals S6 and S7.

When the power of the output signal So is a maximum value in the operation range of the amplifier circuit, the output power of the output signal So is defined as a saturation power Psat. At the saturation power Psat, the output powers of the main amplifier 10a and the peak amplifier 12 in the first comparative example, and the output powers of the control amplifier 10 and the auxiliary amplifiers 12a and 12b in the second comparative example are saturated. The saturation of the output power includes a state where the output power is low in the range of 1 dB or less or 2 dB or less from a complete saturation state. When the power of the output signal So is a minimum value in the operation range of the amplifier circuit, the power is set to the back-off power Pbo. At the back-off power Pbo, the main amplifier 10a starts to be saturated in the first comparative example, and the output power of the control amplifier 10 is saturated in the second comparative example.

Since a high-power signal is not applied to the divider 16, a divider which can be downsized even if the high-frequency characteristic is low can be used. However, a high power is added to the combiner 18. Therefore, a coupler having a high high-frequency characteristic is required for the combiner 18. As the coupler having the high high-frequency characteristic, the distributed constant type branch line coupler as illustrated in FIGS. 3 and 4 is used. However, the distributed constant type branch line coupler uses four λ/4 transmission lines, and therefore, it becomes large in size. Referring to FIG. 4, when the width W2 is large as in the case of the transmission lines TL22 and TL24, an area occupied by the transmission lines TL22 and TL24 becomes large. When the combination ratio of the powers in which the combiner 18 combines the signals S6 and S7 is 1:1, a characteristic impedance Zc1 of the transmission lines TL21 and TL23 at the center frequency fo is the reference impedance Zo. A characteristic impedance Zc2 of the transmission lines TL22 and TL24 at the center frequency fo is Zc1/√2. Therefore, when the dielectric constant and thickness of the dielectric substrate 30 illustrated in FIG. 4 are determined, the widths W1 and W2 of the transmission lines TL21 to TL24 are determined. Therefore, in the first and the second comparative examples, the size of the combiner 18 is increased, and it is difficult to reduce the size of the amplifier circuit 112.

### Third Comparative Example

As a third comparative example, an LMBA in which the combination ratio of the combiner 18 is not 1:1 will be described. Instead of the combination ratio of the combiner 18, a division ratio at which the power of the signal S6 input to the end T21 is divided to the ends T24 and T23 is used as an index. The signal output to the terminal T23 is denoted by a signal S6a, and the signal output to the terminal T24 is denoted by a signal S6b. The amplitudes of the powers of the signals S6, S6a and S6b are denoted by A6, A6a and A6b, respectively. The ratio of the amplitude A6a to the amplitude A6b is A6b:A6a, and it is expressed in dB as A6a−A6b [dB]. The characteristic impedances of the transmission lines TL21 and TL23 in FIGS. 3 and 4 are denoted by Zc1, and the characteristic impedances of the transmission lines TL22 and TL24 in FIGS. 3 and 4 are denoted by Zc2.

Table 1 illustrates the characteristic impedances Zc1 and Zc2 for achieving the ratio A6a−A6b [dB].

TABLE 1

| | A6a-A6b [dB] | | | | | | |
|---|---|---|---|---|---|---|---|
| | −5 | −3 | −2 | 0 | 2 | 3 | 5 |
| Zc1 [Ω] | 28.10 | 35.40 | 39.70 | 50 | 63.00 | 70.60 | 89.00 |
| Zc2 [Ω] | 24.49 | 28.89 | 31.09 | 35.35 | 39.16 | 40.80 | 43.59 |
| \sqrt{2} · | 1.233 | 1.154 | 1.108 | 1.000 | 0.879 | 0.817 | 0.693 |
| Zc2/Zc1 | | | | | | | |

In Table 1, the reference impedance Zo is set to 50Ω. The reference impedance Zo corresponds to impedances viewed from the outside to the ends T21, T22, T23 and T24. As illustrated in Table 1, when the amplitudes A6a and A6b are equal to each other, that is, when the signal S6 is divided equally into S6a and S6b, the characteristic impedance Zc1 is 50Ω of the reference impedance Zo, and the characteristic impedance Zc2 is 35.35Ω which is Zo/√2.

When A6a−A6b is made smaller than 0 dB (<A6a−A6b), the characteristic impedance Zc1 is made lower than the reference impedance Zo, and the characteristic impedance Zc2 is made higher than Zc1/√2. In this case, both the characteristic impedances Zc1 and Zc2 become lower than Zc1 and Zc2 in the case of A6a−A6b=0 dB, respectively. Therefore, the widths W1 and W2 in FIG. 4 are made larger than the widths W1 and W2 in the case of A6a−A6b=0 dB, respectively. Therefore, the size of the combiner 18 is increased.

When A6a−A6b is made larger than 0 dB (>A6a−A6b), the characteristic impedance Zc1 is made higher than the reference impedance Zo, and the characteristic impedance Zc2 is made lower than Zc1/√2. In this case, both the characteristic impedances Zc1 and Zc2 become higher than Zc1 and Zc2 in the case of A6a−A6b=0 dB, respectively. Therefore, the widths W1 and W2 in FIG. 4 are made smaller than the widths W1 and W2 in the case of A6a−A6b=0 dB, respectively. Therefore, the combiner 18 can be downsized.

From the viewpoint of reducing the size of the combiner 18, the characteristic impedance Zc1 is made higher than the reference impedance Zo, and the characteristic impedance Zc2 is made lower than Zc1/√2. The characteristic impedance Zc1 can be se to 1.01 times or more, 1.2 times or more, 1.4 times or more, or 1.7 times or more the reference impedance Zo. The characteristic impedance Zc2 can be 0.99 times or less, 0.85 times or less, 0.7 times or less, or 0.6 times or less Zc1/√2. From the viewpoint of not making A6a−A6b too large, the characteristic impedance Zc1 can be three times or less the reference impedance Zo, and the characteristic impedance Zc2 can be 0.5 times or more Zc1/√2o.

The width W1 can be 0.99 times or less, 0.7 times or less, or 0.5 times or less the width W3. The width W1 can be 0.2 times or more the width W3. The width W2 can be 1.01 times or more, or 1.2 times or more the width W1, and 1.5 times or less the width W1.

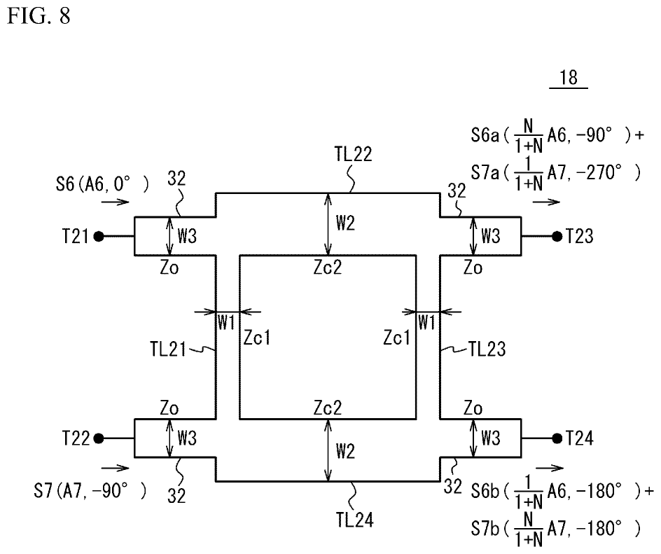

FIG. 8 is a schematic diagram illustrating the operations of the combiner in the third comparative example and the first embodiment. The characteristic impedance of the transmission line 32 is the reference impedance Zo, and is, for example, 50Ω. The width W3 of the transmission line 32 is determined so that the characteristic impedance of the transmission line 32 becomes the reference impedance Zo. As illustrated in Table 1, the characteristic impedance Zc1 of the transmission lines TL21 and TL23 is larger than the reference impedance Zo. Therefore, the width W1 of the transmission lines TL21 and TL23 is smaller than the width W3 of the transmission line 32. The characteristic impedance Zc2 of the transmission lines TL22 and TL24 is smaller than the reference impedance Zo. Therefore, the width W2 of the transmission lines TL22 and TL24 is larger than the width W3 of the transmission line 32.

The amplitude of the signal S6 input to the end T21 is A6, and the phase thereof is 0°. The amplitude of the signal S7 input to the end T22 is A7, and the phase thereof is −90°. The signals S6 and S7 are denoted as (A6, 0°) and (A7, −90°), respectively. The signals S6a and S6b are the signals into which the signal S6 is divided and which are output to the terminals T23 and T24, respectively. A ratio A6b:A6a of the amplitudes of the signals S6b and S6a is denoted as 1:N (N>1). At this time, the signals S6a and S6b are ((N/(1+N))×A6, −90°) and ((1/(1+N))×A6, −180°), respectively. The signals S7a and S7b are ((1/(1+N))× A7, −270°) and ((N/(1+N))×A7, −180°), respectively.

At the end T24, the signals S6b and S7b have the same phase as each other, and the signal S6a having the amplitude of (1/(1+N))×A6 and the signal S7b having the amplitude of (N/(1+N))×A7 are combined.

At the end T23, the signals S6a and S7a have opposite phases. In the case of N=1, the amplitudes of the signals S6a and S7a are ½×A6 and ½×A7, respectively. Since the amplitudes A6 and A7 are substantially the same as each other, the signals S6a and S7a are compensated for each other. As a result, no signal is output from the terminal T23. Thus, the impedance Z1 viewed from the matching circuit 24 to the end T23 is constant regardless of the amplitudes of the signals S6 and S7, and is the reference impedance Zo.

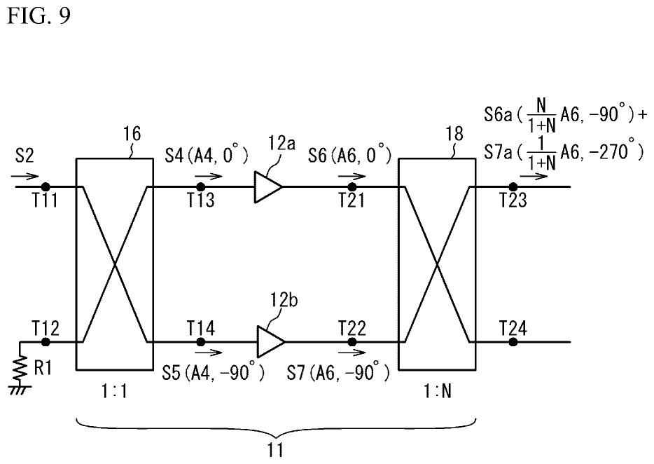

A case of N>1 will be described with reference to the third comparative example. FIG. 9 is a circuit diagram illustrating a balance amplifier in the third comparative example. As illustrated in FIG. 9, in the third comparative example, as described with reference to FIG. 6, the amplitude ratio A6b:A6a of the signals S6b and S6a in the combiner 18 is 1:N (N>1). The ratio of the amplitude of the signal S5 to the amplitude of the signal S4 in the divider 16 is 1:1. Therefore, the signal S4 output to the end T13 is (A4, 0°). The signal S5 output from the end T14 is (A4, −90°). The amplitudes of the signals S4 and S5 are substantially the same as each other, and are A4. The auxiliary amplifiers 12a and 12b have the same physical size and the same saturation power. The input bias voltages supplied to the auxiliary amplifiers 12a and 12b are the same as each other, and the output bias voltages are also the same as each other. Thus, the amplitudes of the signals S6 and S7 are substantially the same, and are A6. Therefore, the signal S6 input to the end T21 is (A6, 0°), and the signal S7 input to the end T22 is (A6, −90°).

The signal S6a output from the end T23 is ((N/(1+N))×A6, −90°), and the signal S7a is ((1/(1+N))×A6, −270°). Since the signals S6a and S7a are opposite in phase, the signal S6a+S7a is ((N−1)/(1+N)× A6, −90°), and the signals S6a and Sa are not compensated in the case of N>1. Therefore, the impedance Z1, which is the load of the control amplifier 10, changes. For example, when the output power Pout is the back-off power Pbo, the impedance Z1 is the reference impedance Zo. When the output power Pout is the saturation power Psat, the impedance Z1 changes from the reference impedance Zo due to the influence of the signal S6a+S7a output from the end T23 of the combiner 18.

### Example 1 of First Embodiment

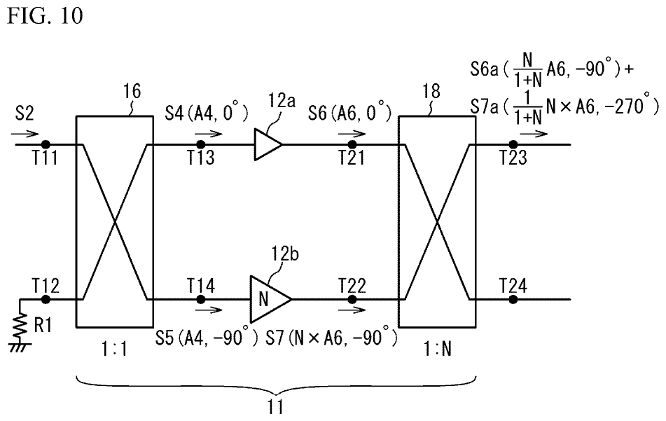

FIG. 10 is a circuit diagram illustrating a balance amplifier in an example 1 of the first embodiment. As illustrated in FIG. 10, the division ratio of the signal of the divider 16 is 1:1. The physical size of the auxiliary amplifier 12b is about N times the physical size of the auxiliary amplifier 12a. For example, when the auxiliary amplifiers 12a and 12b are FETs, the gate width of the auxiliary amplifier 12b is about N times the gate width of the auxiliary amplifier 12a. The saturation power of the auxiliary amplifier 12b is about N times the saturation power of the auxiliary amplifier 12a.

The amplitudes of the signals S4 and S5 divided by the divider 16 are substantially the same as each other, and are A4. When both the auxiliary amplifiers 12a and 12b are used at the saturation power, the amplitude A7 of the signal S7 is N times the amplitude A6 of the signal S6. Therefore, the signal S6 input to the end T21 is (A6, 0°), and the signal S7 input to the end T22 is (N×A6, −90°).

The signal S6a output from the end T23 is ((N/(1+N))× A6, −90°), and the signal S7a is ((1/(1+N))×N×A6, −270°). The amplitudes of the signals S6a and S7a are both (N/(1+N)×A6). Since the signals S6a and S7a are opposite in phase, the amplitude of S6a+S7a is substantially zero. Thus, when the output power Pout is the back-off power Pbo and when the output power Pout is the saturation power Psat, the impedance Z1 is the reference impedance Zo.

### Example 2 of First Embodiment

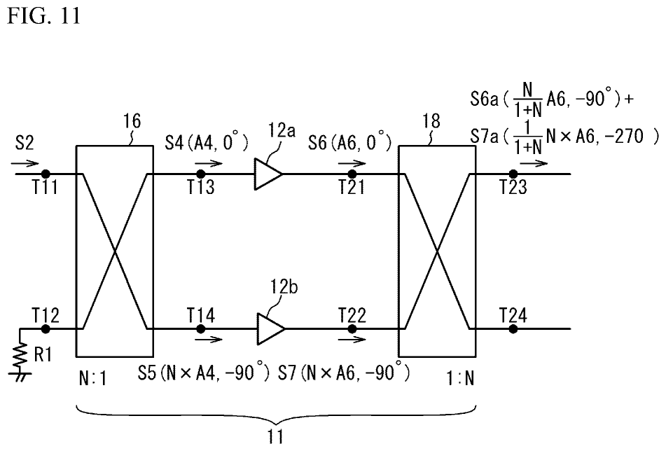

FIG. 11 is a circuit diagram illustrating a balance amplifier in an example 2 of the first embodiment. As illustrated in FIG. 11, the division ratio of the signal of the divider 16 is N:1. The physical sizes of the auxiliary amplifiers 12a and 12b are substantially the same as each other. The saturation powers of the auxiliary amplifiers 12a and 12b are substantially the same as each other. The method of setting the division ratio of the divider 16 to N:1 is performed by setting the characteristic impedance of the transmission lines TL11 to TL14 to the value as illustrated in Table 1 when the divider 16 is the branch line coupler. Even when another coupler is used for the divider 16, the division ratio can be changed by using a known method.

The amplitude of the signal S5 divided by the divider 16 is about N times the amplitude of the signal S4. Thus, the signal S4 is (A4, 0°) and the signal S5 is (N×A4, −90°). If the auxiliary amplifiers 12a and 12b do not reach the saturation power and the power gains thereof are substantially the same as each other, the amplitude A7 of the signal S7 is N times the amplitude of the signal S6. Thus, the signal S6 is (A6, 0°) and the signal S7 is (N× A6, −90°).

Therefore, as in the example 1, the signal S6a output from the end T23 is ((N/(1+N))×A6, −90°), and the signal S7a is ((1/(1+N))×N×A6, −270°). The amplitude of S6a+S7a is almost zero. Therefore, even if the magnitude of the signals S6 and S7 changes, the change in the impedance Z1 is suppressed.

According to the first embodiment, the characteristic impedance Zc1 (first characteristic impedance) of the transmission lines TL21 and TL23 at the center frequency fo in the branch line coupler is higher than the reference impedance Zo. The characteristic impedance Zc2 (second characteristic impedance) of the transmission lines TL22 and TL24 at the center frequency fo is lower than Zc1/√2. Thereby, the combiner 18 can be downsized as illustrated in Table 1. However, as in the third comparative example, the impedance Z1 viewed from the control amplifier 10 to the combiner 18 changes due to the change in the signals S6 and S7. Therefore, the amplitude of the power of the signal S7 is made larger than the amplitude of the power of the signal S6. This makes it possible to make the signal S6a+S7a output from the terminal T23 small, as in the examples 1 and 2 of the first embodiment. Therefore, the change in the impedance Z1 due to the change in the signals S6 and S7 can be suppressed.

A first ratio of the amplitude A7 of the power of the signal S7 to the amplitude A6 of the power of the signal S6 is A7/A6. A second ratio of the amplitude Aba of the power of the signal S6a (eighth signal) divided from the signal S6 having the center frequency fo input to the end T21 to the power amplitude A6b (ninth signal) of the signal S6b divided from the signal S6 is A6a/A6b. The signal S6a and the signal S6b are transmitted to the end T23 and the end T2, respectively. When the first ratio A7/A6 and the second ratio A6a/A6b are expressed in dB, and both the first ratio and the second ratio are N as in the examples 1 and 2 of the first embodiment, a difference between the first ratio A7/A6 and the second ratio A6a/A6b is 0 dB. At this time, the signal S6a+S7a output from the terminal T23 becomes substantially 0. From the viewpoint of suppressing the change in the impedance Z1 depending on the magnitude of the signals S6 and S7, the difference between the first ratio A7/A6 and the second ratio A6a/A6b can be 1 dB or less, 0.5 dB or less, or 0.3 dB or less. The difference between A7/A6 and A6a/A6b corresponds to |A7/A6−A6a/A6b|.

From the viewpoint of downsizing the combiner 18, the second ratio A6a/A6b can be 2 dB or more, 3 dB or more, or 4 dB or more. The characteristic impedance Zc1 can be 1.2 times or more, 1.4 times or more, or 1.6 times or more the reference impedance Zo. The characteristic impedance Zc2 can be 0.9×Zc1/√2 or less, 0.8×Zc1/√2 or less, or 0.7×Zc1/√2 or less.

If the second ratio A6a/A6b is too large, the signal output from the end T24 is degraded. From this viewpoint, the second ratio A6a/A6b can be 10 dB or less. The characteristic impedance Zc1 can be three times or less the reference impedance Zo. The characteristic impedance Zc2 can be 0.3×Zx1/√2 or more.

When the characteristic impedances Zc1 and Zc2 are set as described above, the width W1 (first width) of the transmission lines TL21 and TL23 becomes smaller than the width W3 (second width) of the transmission line 32 (fifth transmission line) connected to the ends T21, T22, T23, and T24. The width W2 (third width) of the transmission lines TL22 and TL24 is larger than the width W1.

From the viewpoint of increasing the second ratio A6a/A6b, the width W1 can be 0.7 times or less or can be 0.5 times or less the width W3. The width W2 can be 2.1 times or more or 2.5 times or more the width W1. From the viewpoint of not making the second ratio A6a/A6b too large, the width W1 can be 0.2 times or more the width W3, and the width W2 can be 10 times or less the width W1.

As in the example 1 of the first embodiment, from the viewpoint of increasing the first ratio A7/A6, the saturation power of the auxiliary amplifier 12b is larger than the saturation power of the auxiliary amplifier 12a. The saturation power of the auxiliary amplifier 12b with respect to the saturation power of the auxiliary amplifier 12a can be 1 dB or more, 2 dB or more, or 3 dB or more. From the viewpoint of not making the first ratio A7/A6 too large, the saturation power of the auxiliary amplifier 12b with respect to the saturation power of the auxiliary amplifier 12a can be 10 dB or less.

In order to make the saturation power of the auxiliary amplifier 12b larger than the saturation power of the auxiliary amplifier 12a, the physical size of the auxiliary amplifier 12b is larger than the physical size of the auxiliary amplifier 12a. For example, when the auxiliary amplifiers 12a and 12b are FETs, the gate width of the auxiliary amplifier 12b can be made larger than the gate width of the auxiliary amplifier 12a, and can be made 1.3 times or more, 1.6 times or more, or 2 times or more the gate width of the auxiliary amplifier 12a. The gate width of the auxiliary amplifier 12b can be 10 times or less the gate width of the auxiliary amplifier 12a.

As in the example 2 of the first embodiment, from the viewpoint of increasing the first ratio A7/A6, the amplitude A5 of the power of the signal S5 is larger than the amplitude A4 of the power of the signal S4. The ratio of the amplitude A5 of the power of the signal S5 to the amplitude A4 of the power of the signal S4 can be 1 dB or more, can be 2 dB or more, or can be 3 dB or more. From the viewpoint of not making the first ratio A7/A6 too large, the ratio of the amplitude A5 to the amplitude A4 can be 10 dB or less.

As a method of making the first ratio A7/A6 larger than 1, there is a method of combining the example 1 and the example 2, for example, other than any one of the examples 1 and 2 of the first embodiment. That is, the saturation power of the auxiliary amplifier 12b may be made larger than the saturation power of the auxiliary amplifier 12a, and the amplitude A5 of the power of the signal S5 may be made larger than the amplitude A4 of the power of the signal S4. The first ratio A7/A6 may be made larger than 1 by appropriately setting the bias voltages of the auxiliary amplifiers 12a and 12b.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. An amplifier circuit comprising:
a first divider that divides an input signal into a first signal and a second signal;
a control amplifier that amplifies the first signal and outputs an amplified signal as a third signal;
a second divider that divides the second signal into a fourth signal and a fifth signal having different phases at a center frequency of an operating band;
a first auxiliary amplifier that amplifies the fourth signal and outputs an amplified signal as a sixth signal;
a second auxiliary amplifier that amplifies the fifth signal and outputs an amplified signal as a seventh signal; and
a branch line coupler including:
a first end to which the sixth signal is input;
a second end to which the seventh signal is input;
a third end to which the third signal is input;
a fourth end from which an output signal is output;
a first transmission line connecting the first end to the second end;
a second transmission line connecting the first end to the third end;
a third transmission line connecting the third end to the fourth end; and
a fourth transmission line connecting the second end to the fourth end,
wherein a first characteristic impedance at the center frequency of the first transmission line and the third transmission line is higher than a reference impedance, and a second characteristic impedance at the center frequency of the second transmission line and the fourth transmission line is lower than the first characteristic impedance/√2,
wherein an amplitude of a power of the seventh signal is larger than an amplitude of a power of the sixth signal.

2. The amplifier circuit according to claim 1, wherein
a difference between a first ratio of the amplitude of the power of the seventh signal to an amplitude of the power of the sixth signal and a second ratio of an amplitude of a power of an eighth signal divided from the sixth signal having the center frequency input to the first end to an amplitude of a power of a ninth signal divided from the sixth signal is 1 dB or less, the eighth signal and the ninth signal being transmitted to the third terminal and the fourth end, respectively.

3. The amplifier circuit according to claim 2, wherein
the second ratio is 2 dB or more.

4. The amplifier circuit according to claim 1, wherein
the first characteristic impedance is 1.2 times or more the reference impedance, and the second characteristic impedance is 0.9/√2 times or less the first characteristic impedance.

5. The amplifier circuit according to claim 1, wherein
first widths of the first transmission line and the third transmission line are smaller than second widths of fifth transmission lines connected to the first end, the second end, the third end, and the fourth end, and
third widths of the second transmission line and the fourth transmission line are larger than the first widths.

6. The amplifier circuit according to claim 1, wherein
a saturation power of the second auxiliary amplifier is larger than a saturation power of the first auxiliary amplifier.

7. The amplifier circuit according to claim 1, wherein
a ratio of a saturation power of the second auxiliary amplifier to a saturation power of the first auxiliary amplifier is 2 dB or more.

8. The amplifier circuit according to claim 1, wherein
a physical size of the second auxiliary amplifier is larger than a physical size of the first auxiliary amplifier.

9. The amplifier circuit according to claim 1, wherein
an amplitude of a power of the fifth signal is larger than an amplitude of a power of the fourth signal.

10. The amplifier circuit according to claim 9, wherein
a ratio of the amplitude of the power of the fifth signal to the amplitude of the power of the fourth signal is 2 dB or more.
